(19) United States
(12) Patent Application Publication
(10) Pub. No.: US 2026/0178791 A1
(43) Pub. Date: Jun. 25, 2026

(54) IDENTIFYING A DESIGN OF AN INFRASTRUCTURE OF CLOUD AND EDGE COMPUTING RESOURCES OF AN INDUSTRIAL FACILITY THAT OPTIMALLY SERVICES THE USER

(71) Applicant: International Business Machines Corporation, Armonk, NY (US)

(72) Inventors: Sudheesh S. Kairali, Kerala (IN); Sarbajit Kumar Rakshit, Kolkata (IN)

(21) Appl. No.: 18/991,587

(22) Filed: Dec. 22, 2024

(51) Int. Cl. G06F 30/18; G06F 30/27

(52) U.S. Cl. CPC G06F 30/18; G06F 30/27

(57) ABSTRACT

Described are techniques for identifying a design of an infrastructure on an industrial floor to service a user. A knowledge corpus of information to be used as a sample data set for training a machine learning model is generated, which includes information, such as mobility patterns of users on the industrial floor for various manufacturing process flows, and interaction of users on the industrial floor with different services at different locations on the industrial floor for various manufacturing process flows. A machine learning model is then trained to identify the designs of the infrastructure on the industrial floor based on the knowledge corpus. Upon receiving the requirements of a service level agreement and the current manufacturing process flow, the trained machine learning model is used to identify a particular design of the infrastructure of cloud and edge computing resources on the industrial floor that optimally services the user.

### TECHNICAL FIELD

The present disclosure relates generally to infrastructure designs for an industrial facility.

### BACKGROUND

Infrastructure design for an industrial facility involves planning, developing, and implementing the systems that make the facility function, including: electricity, transportation, water, telecommunications, and data transmission.

### SUMMARY

In one embodiment of the present disclosure, a computer-implemented method for identifying a design of an infrastructure on an industrial floor to service a user comprises generating a knowledge corpus comprising mobility patterns used by users on the industrial floor and interactions of the users on the industrial floor with different services at different locations on the industrial floor for various manufacturing process flows based on simulating activities being performed by the users while on the industrial floor for various manufacturing process flows. The method further comprises training a machine learning model to identify designs of infrastructure on the industrial floor based on the knowledge corpus. The method additionally comprises receiving requirements of a service level agreement. Furthermore, the method comprises receiving a current manufacturing process flow. Additionally, the method comprises identifying the design of the infrastructure on the industrial floor using the trained machine learning model based on the received requirements of the service level agreement and the current manufacturing process flow.

Other forms of the embodiment of the computer-implemented method described above are in a system and in a computer program product.

The foregoing has outlined rather generally the features and technical advantages of one or more embodiments of the present disclosure in order that the detailed description of the present disclosure that follows may be better understood. Additional features and advantages of the present disclosure will be described hereinafter which may form the subject of the claims of the present disclosure.

### BRIEF DESCRIPTION OF THE DRAWINGS

A better understanding of the present disclosure can be obtained when the following detailed description is considered in conjunction with the following drawings, in which:

FIG. 1 illustrates an embodiment of the present disclosure of a communication system for practicing the principles of the present disclosure;

FIG. 2 is a diagram of the software components used by the industrial designer for identifying a design of an infrastructure of cloud and edge computing resources on the industrial floor of the industrial facility that optimally services the user, such as the user located on the industrial floor, in accordance with an embodiment of the present disclosure;

FIG. 3 illustrates a design of the infrastructure (infrastructure of cloud and edge computing resources) on the industrial floor of the industrial facility that optimally services the user, such as the user on the industrial floor, based on the requirements of a service level agreement and a current manufacturing process flow in accordance with an embodiment of the present disclosure;

FIG. 4 illustrates an embodiment of the present disclosure of the hardware configuration of the infrastructure designer which is representative of a hardware environment for practicing the present disclosure;

FIG. 5 is a flowchart of a method for training a machine learning model to identify a design of the infrastructure on the industrial floor based on the requirements of a service level agreement and a current manufacturing process flow in accordance with an embodiment of the present disclosure;

FIG. 6 is a flowchart of a method for generating a knowledge corpus to be used as a sample data set for training the machine learning model in accordance with an embodiment of the present disclosure;

FIG. 7 is a flowchart of a method for identifying a design of an infrastructure of cloud and edge computing resources of an industrial facility that optimally services the user, such as the user on the industrial floor, in accordance with an embodiment of the present disclosure; and

FIG. 8 is a flowchart of a method for identifying the design of the infrastructure on the industrial floor using the trained machine learning model in accordance with an embodiment of the present disclosure.

### DETAILED DESCRIPTION

As stated above, infrastructure design for an industrial facility involves planning, developing, and implementing the systems that make the facility function, including: electricity, transportation, water, telecommunications, and data transmission.

Some key considerations for industrial facility design include: strategic planning, automation, facility size and expansion, employee safety and comfort, sustainable design, specialized uses and equipment, column bay spacing, etc.

Some tools and technologies that can help with the infrastructure design of the industrial facility include building information modeling, which corresponds to a physical and functional model of the facility that helps with visualization, analysis, and improvement.

Unfortunately, such tools and technologies do not assist in designing the infrastructure of cloud and edge computing resources utilized at the industrial facility. For example, there are currently no tools or technologies to assist in designing the infrastructure of cloud and edge computing resources utilized at the industrial facility that optimally services the user (i.e., provides the best possible service to the user at the minimum cost), including the user on the industrial floor.

The embodiments of the present disclosure provide a means for identifying the design of the infrastructure of cloud and edge computing resources of the industrial facility that optimally services the user, such as the user on the industrial floor. In one embodiment, simulation is performed to generate a knowledge corpus of information that is used as a sample data set to train a machine learning model to identify the design of the infrastructure on the industrial floor of the industrial facility based on the requirements of a service level agreement and a current manufacturing process flow. A simulation, as used herein, refers to an imitative representation of a process utilized at an industrial facility, such as by the users or workers located on the industrial floor. An industrial facility, as used herein, refers to a complex (e.g., manufacturing plant) which may consist of one or more buildings that include an industrial floor infrastructure. The infrastructure, as used herein, refers to the physical systems that make the industrial facility function, including the cloud and edge computing resources. Cloud and edge computing resources, as used herein, refer to computing resources from both a hybrid cloud and edge computing. A hybrid cloud, as used herein, refers to a computing environment that combines a private cloud with a public cloud, or with on-premises infrastructure. Edge computing, as used herein, refers to a distributed computing framework that processes and stores data closer to the devices that generate it, rather than a central data center.

As discussed above, a knowledge corpus of information is used as a sample data set to train a machine learning model to identify the design of the infrastructure on the industrial floor of the industrial facility based on the requirements of a service level agreement and a current manufacturing process flow. A service level agreement, as used herein, refers to a contract between a service provider and a customer that outlines the services to be provided, the standards to be met, and how performance will be measured. A manufacturing process flow, as used herein, refers to a detailed description of each step in the process of manufacturing a product, including a listing of activities to be performed at different locations on the industrial floor involving services provided by the cloud and edge computing resources. Services, as used herein, refer to the software functionalities, such as complex computations, data processing, etc. involving the activities (e.g., virtual reality interaction, augmented reality interaction, controlling forklifts, utilizing caustic cleaning solutions) being performed during the manufacturing process flow.

In one embodiment, such a knowledge corpus of information includes information, such as the mobility patterns (use of mobile devices and applications to enable factory workers to access information, complete tasks, and communicate effectively while moving around the industrial floor) of users on the industrial floor for various manufacturing process flows, interaction of users on the industrial floor with different services at different locations on the industrial floor for various manufacturing process flows, contextual situations and allowed latency in accessing various services on the industrial floor during various manufacturing process flows during the contextual situations, physical locations of machines on the industrial floor utilizing cloud and edge computing services based on the requirements of service level agreements, etc. In one embodiment, such a knowledge corpus of information is obtained via simulation of the industrial facility implementing manufacturing process flows.

In one embodiment, a machine learning model is trained to identify a design of the infrastructure of cloud and edge computing resources on the industrial floor of the industrial facility that optimally services the user, such as the user on the industrial floor, based on the requirements of the service level agreement and the current manufacturing process. In one embodiment, such a design of the infrastructure on the industrial floor is identified based on identifying how much cloud and edge computing resources need to be available at the different locations of the industrial floor based on the activities to be performed at different locations of the industrial floor using the trained machine learning model based on the current manufacturing process flow. In one embodiment, such a design of the infrastructure on the industrial floor is identified based on identifying machines (e.g., industrial personal computers (PCs), panel PCs, etc. that provide services supported by the cloud and edge computing resources) on the industrial floor to be aligned with the activities to be performed at the different locations of the industrial floor based on the requirements of the service level agreement.

In this manner, the design of an infrastructure of cloud and edge computing resources on the industry floor of the industrial facility that optimally services the user, such as the user on the industrial floor, can be identified. These and other features will be discussed in further detail below.

In some embodiments of the present disclosure, the present disclosure comprises a computer-implemented method, system, and computer program product for identifying a design of an infrastructure on an industrial floor to service a user. In one embodiment of the present disclosure, a knowledge corpus of information to be used as a sample data set for training a machine learning model to identify a design of the infrastructure on the industrial floor based on the requirements of a service level agreement and a current manufacturing process flow is generated. In one embodiment, such a knowledge corpus of information includes information, such as the mobility patterns (use of mobile devices and applications to enable factory workers to access information, complete tasks, and communicate effectively while moving around the industrial floor) of users on the industrial floor for various manufacturing process flows, interaction of users on the industrial floor with different services at different locations on the industrial floor for various manufacturing process flows, contextual situations and allowed latency in accessing various services on the industrial floor during various manufacturing process flows during the contextual situations, physical locations of machines on the industrial floor utilizing cloud and edge computing services based on requirements of the service level agreements, etc. In one embodiment, a machine learning model is trained to identify the designs of the infrastructure on the industrial floor of the industrial facility based on the knowledge corpus. Upon receiving the requirements of a service level agreement and the current manufacturing process flow, the trained machine learning model is used to identify the design of the infrastructure of cloud and edge computing resources on the industrial floor of the industrial facility that optimally services the user, such as the user on the industrial floor, based on the requirements of the service level agreement and the current manufacturing process. In this manner, the design of an infrastructure of cloud and edge computing resources on the industry floor of the industrial facility that optimally services the user, such as the user on the industrial floor, can be identified.

In the following description, numerous specific details are set forth to provide a thorough understanding of the present disclosure. However, it will be apparent to those skilled in the art that the present disclosure may be practiced without such specific details. In other instances, well-known circuits have been shown in block diagram form in order not to obscure the present disclosure in unnecessary detail. For the most part, details considering timing considerations and the like have been omitted inasmuch as such details are not necessary to obtain a complete understanding of the present disclosure and are within the skills of persons of ordinary skill in the relevant art.

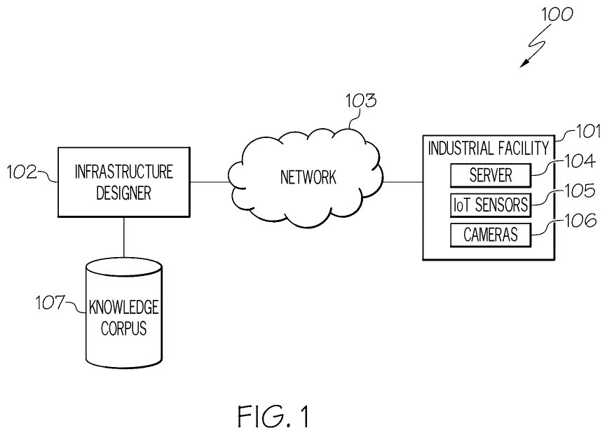

Referring now to the Figures in detail, FIG. 1 illustrates an embodiment of the present disclosure of a communication system 100 for practicing the principles of the present disclosure. Communication system 100 includes an industrial facility 101 connected to a infrastructure designer 102 via a network 103.

An “industrial facility” 101, as used herein, refers to a complex (e.g., manufacturing plant) which may consist of one or more buildings that include an industrial floor infrastructure. An industrial floor infrastructure, as used herein, refers to the machines, devices, robots, etc. that operate on the industrial floor (floor, such as concrete, used in industrial and commercial settings, such as a plant) of industrial facility 101 to manufacture and produce parts, goods, pieces, etc. For example, such an industrial floor infrastructure may include robots that weld and assemble parts. In another example, such an industrial floor infrastructure may include computer numerical control machines to cut metal pieces to a precise specification. In a further example, such an industrial floor infrastructure may include engine machining stations used to create engine blocks.

The “machines” on the industrial floor infrastructure, as used herein, refer to a computing device, such as an industrial personal computer, panel personal computer, etc., that provides services supported by the cloud and edge computing resources. Furthermore, in one embodiment, such machines may also manufacture work products (e.g., welding and assembling parts, cutting metal pieces to a precise specification, etc.). Services, as used herein, refer to the software functionalities, such as complex computations, data processing, etc. involving the activities (e.g., virtual reality interaction, augmented reality interaction, controlling forklifts, utilizing caustic cleaning solutions) being performed during the manufacturing process flow.

In the illustration of FIG. 1, the interconnection of industrial facility 101 to infrastructure design 102 via network 103 is accomplished via a server 104.

In one embodiment, server 104 stores data regarding the capabilities of the industrial floor infrastructure and the automation software used to control such industrial floor infrastructure. “Automation software,” as used herein, refers to applications that minimize the need for human input and are designed to turn repeatable, routine tasks into automated actions. For example, server 104 stores data regarding the capabilities of the industrial floor infrastructure (e.g., machines, devices, robots, etc.) being utilized in industrial facility 101, such as loading and unloading parts, material handling, transferring finished parts to post-processing, drilling, welding, painting, product inspection, picking and placing, die casting, glass making, grinding, etc. In one embodiment, such capabilities are stored for each particular machine, device, robot, etc. of the industrial floor infrastructure, such as in a data structure (e.g., table), which is stored in a storage device of server 104. Furthermore, server 104 stores data regarding the capabilities of the automation software, such as the manipulation of objects (e.g., panel) or tools (e.g., moving welding equipment along multiple axes), operations (e.g., motion control, positioning control, torque control, etc.), etc. In one embodiment, such capabilities are stored for each particular automation software being utilized, including for each version or update for such automation software, such as in a data structure (e.g., table), which is stored in a storage device of server 104.

In one embodiment, the data regarding the capabilities of the industrial floor infrastructure and the automation software used to control such industrial floor infrastructure is obtained and stored by server 104 from Internet of Things (IoT) sensors 105. IoT sensor 105, as used herein, refers to a sensor that can be attached to a machine, device, robot, etc. of the industrial floor infrastructure. Furthermore, IoT sensors 105 are configured to exchange data with other devices and systems over a network, such as network 103. In one embodiment, IoT sensors 105 are configured to monitor the industrial floor infrastructure (e.g., machines, devices, robots, etc.) at industrial facility 101. For example, IoT sensors 105 may monitor the capabilities of the machines, devices, robots, etc. (industrial floor infrastructure), such as loading and unloading parts, material handling, transferring finished parts to post-processing, drilling, welding, painting, product inspection, picking and placing, die casting, glass making, grinding, etc. Such data may then be captured by IoT sensors 105 and relayed to server 104 to be stored, such as in a storage device of server 104.

In one embodiment, such IoT sensors 105 may be attached to machines, such as computing machines that provide services supported by the cloud and edge computing resources. In one embodiment, such IoT sensors 105 may be attached to the users, such as the workers, on the industrial floor. By attaching IoT sensors 105 to such machines and/or users, the physical activities of the users, including the interactions of the users with such machines, may be monitored and captured. For example, activities, such as controlling forklifts remotely, utilizing caustic cleaning solutions, virtual reality interaction, augmented reality interaction, etc., that are utilized by the users during the manufacturing process flow are monitored and captured by IoT sensors 105. Such captured data may then be relayed to server 104 to be stored, such as in a storage device of server 104, or may be directly relayed to infrastructure designer 102, to be stored in the storage device of infrastructure designer 102.

In one embodiment, industrial facility 101 further includes cameras 106 configured to capture images of physical activity occurring at various locations within industrial facility 101. In one embodiment, such cameras 106 are installed at strategic locations within industrial facility 101 to capture images of physical activity occurring at various locations within industrial facility 101, such as user interactions with the computing machines that provide services supported by the cloud and edge computing resources. Cameras 106 may be still cameras and/or video cameras. Camera 106 may be mechanically movable, for example, by mounting camera 106 on a rotating and/or tilting a platform. In one embodiment, such captured data may then be relayed to server 104 to be stored, such as in a storage device of server 104, or may be directly relayed to infrastructure designer 102, to be stored in the storage device of infrastructure designer 102.

In one embodiment, infrastructure designer 102 is configured to identify a design of an infrastructure of cloud and edge computing resources on the industrial floor of industrial facility 101 that optimally services the user, such as the user located on the industrial floor.

In one embodiment, infrastructure designer 102 performs simulations of industrial facility 101 implementing manufacturing process flows. In one embodiment, in such simulations, a knowledge corpus of information is created, which is stored in database 107 connected to infrastructure designer 102. In one embodiment, such a knowledge corpus of information includes information, such as the mobility patterns (use of mobile devices and applications to enable factory workers to access information, complete tasks, and communicate effectively while moving around the industrial floor) of users on the industrial floor for various manufacturing process flows, interaction of users on the industrial floor with different services at different locations on the industrial floor for various manufacturing process flows, contextual situations and allowed latency in accessing various services on the industrial floor during various manufacturing process flows during the contextual situations, physical locations of machines on the industrial floor utilizing cloud and edge computing services based on the requirements of the service level agreements, etc.

In one embodiment, infrastructure designer 102 trains a machine learning model based on the information stored in the knowledge corpus, which is used as a sample data set, to identify the design of the infrastructure of cloud and edge computing resources on the industrial floor of industrial facility 101 that optimally services the user, such as the user located on the industrial floor, based on the requirements of the service level agreement and the current manufacturing process.

In one embodiment, such a design of the infrastructure on the industrial floor is identified based on identifying how much cloud and edge computing resources need to be available at the different locations of the industrial floor based on the activities to be performed at different locations of the industrial floor using the trained machine learning model based on the current manufacturing process flow. In one embodiment, such a design of the infrastructure on the industrial floor is identified based on identifying the machines (e.g., industrial personal computers (PCs), panel PCs, etc. that provide services supported by the cloud and edge computing resources) on the industrial floor to be aligned with the activities to be performed at the different locations of the industrial floor based on the requirements of the service level agreement.

In this manner, the design of an infrastructure of cloud and edge computing resources on the industrial floor of industrial facility 101 that optimally services the user, such as the user on the industrial floor, can be identified. A further discussion regarding these and other features is provided below.

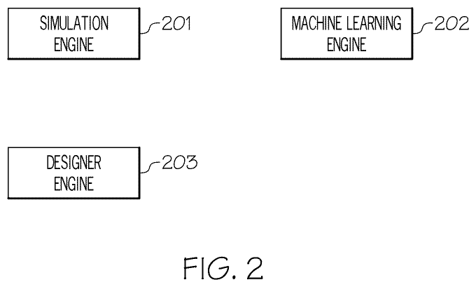

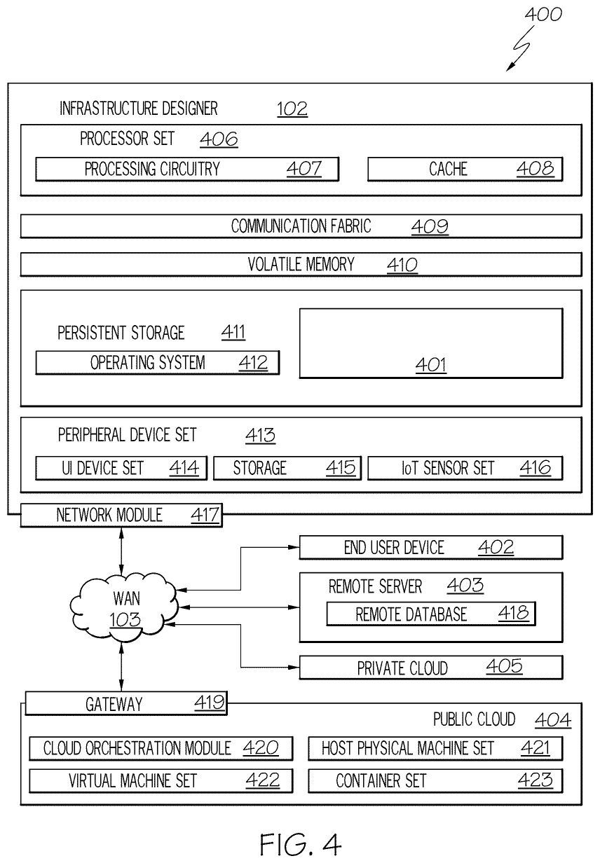

A description of the software components of infrastructure designer 102 used for designing an infrastructure of cloud and edge computing resources on the industrial floor of industrial facility 101 that optimally services the user, such as the user on the industrial floor, is provided below in connection with FIG. 2. A description of the hardware configuration of infrastructure designer 102 is provided further below in connection with FIG. 4.

As discussed above, industrial facility 101 is connected to a infrastructure designer 102 via network 103.

Network 103 may be, for example, a local area network, a wide area network, a wireless wide area network, a circuit-switched telephone network, a Global System for Mobile Communications (GSM) network, a Wireless Application Protocol (WAP) network, a WiFi network, an IEEE 802.11 standards network, various combinations thereof, etc. Other networks, whose descriptions are omitted here for brevity, may also be used in conjunction with system 100 of FIG. 1 without departing from the scope of the present disclosure.

System 100 is not to be limited in scope to any one particular network architecture. System 100 may include any number of industrial facilities 101, industrial designers 102, networks 103, servers 104, IoT sensors 105, cameras 106, and databases 107.

A discussion regarding the software components used by industrial designer 102 for identifying a design of an infrastructure of cloud and edge computing resources on the industrial floor of industrial facility 101 that optimally services the user, such as the user located on the industrial floor, is provided below in connection with FIG. 2

FIG. 2 is a diagram of the software components used by industrial designer 102 for identifying a design of an infrastructure of cloud and edge computing resources on the industrial floor of industrial facility 101 that optimally services the user, such as the user located on the industrial floor, in accordance with an embodiment of the present disclosure.

Referring to FIG. 2, in conjunction with FIG. 1, industrial designer 102 includes simulation engine 201 configured to generate a knowledge corpus of information stored in database 107, which includes information, such as the mobility patterns (use of mobile devices and applications to enable factory workers to access information, complete tasks, and communicate effectively while moving around the industrial floor) of users on the industrial floor for various manufacturing process flows, interaction of users on the industrial floor with different services at different locations on the industrial floor for various manufacturing process flows, contextual situations and allowed latency in accessing various services on the industrial floor during various manufacturing process flows during the contextual situations, physical locations of machines on the industrial floor utilizing cloud and edge computing services based on the requirements of service level agreements, etc. In one embodiment, such a knowledge corpus is used as a sample data set for training a machine learning model to identify the design of an infrastructure of cloud and edge computing resources on the industrial floor of industrial facility 101 that optimally services the user, such as the user on the industrial floor.

In one embodiment, simulation engine 201 receives historical data related to the types of activities being performed by users (e.g., workers) while on the industrial floor of industrial facility 101 for various manufacturing process flows. In one embodiment, such data may be stored in server 104 and later populated in the knowledge corpus of database 107.

In one embodiment, such data pertaining to the types of activities being performed by the users while on the industrial floor is acquired by monitoring and capturing the interactions of the users with machines via IoT sensors 105 and cameras 106. For example, activities, such as controlling forklifts remotely, utilizing caustic cleaning solutions, virtual reality interaction, augmented reality interaction, etc., that are utilized by the users via their interactions with the machines on the industrial floor utilizing cloud and edge computing services during the manufacturing process flow are monitored and captured by IoT sensors 105 and cameras 106. In one embodiment, such data may be stored in server 104 and later populated in the knowledge corpus of database 107.

In one embodiment, simulation engine 201 identifies the mobility patterns used by the users and the interaction of the users on the industrial floor with different services at different locations on the industrial floor for various manufacturing process flows based on such received historical data via simulation. A mobility pattern, as used herein, refers to the use of mobile devices and applications to enable users, such as factory workers, to access information, complete tasks, and communicate effectively while moving around the industrial floor. A service, as used herein, refers to the software functionalities, such as complex computations, data processing, etc. involving the activities (e.g., virtual reality interactions, controlling forklifts, utilizing caustic cleaning solutions, etc.) being performed during the manufacturing process flow.

In one embodiment, simulation engine 201 models worker moments, service points, and different manufacturing process flows enabling the analysis of user interactions on the industrial floor with different services at different locations on the industrial floor for various manufacturing process flows. In one embodiment, simulation engine 201 utilizes various simulation tools to perform such a simulation, which can include, but are not limited to, AnyLogic®, FlexSim®, Arena, Siemens® Tecnomatix® Plant Simulation, Virtual Components, etc.

In one embodiment, such simulation tools simulate user movements throughout industrial facility 101 considering factors, such as walking speed, waiting times at the machines on the industrial floor utilizing cloud and edge computing services, and potential interruptions. Such factors may be determined using the historical data pertaining to the types of activities being performed by the users while on the industrial floor for various manufacturing process flows.

In one embodiment, such simulation tools simulate service interactions, such as which information is accessed, which tasks are completed, etc. using the machines on the industrial floor utilizing cloud and edge computing services. Such service interactions may be determined using the historical data pertaining to the types of activities being performed by the users while on the industrial floor for various manufacturing process flows. For example, such service interactions may include the type of machine, the services processed by such a machine and the required amount of cloud and edge computing resources to provide such services.

In one embodiment, such simulation results are stored in database 107 as part of the knowledge corpus. That is, in one embodiment, the identified mobility patterns used by the users and the interaction of the users on the industrial floor with different services at different locations on the industrial floor for various manufacturing process flows are stored in the knowledge corpus of database 107.

In one embodiment, simulation engine 201 receives data pertaining to different contextual situations that can occur on the industrial floor of industrial facility 101 for various manufacturing process flows. Contextual situations, as used herein, refer to events, such as batches, runs, shifts, or any other event that has a start and end time, that involve users and the machines on the industrial floor utilizing cloud and edge computing services to handle services requested by the users during the manufacturing process flows. In one embodiment, such data relates to historical data. In one embodiment, such data is provided by an expert, such as a subject matter expert. In one embodiment, such data may be stored in server 104 and later populated in the knowledge corpus of database 107.

In one embodiment, such data pertaining to different contextual situations that can occur on the industrial floor of industrial facility 101 are monitored and captured by IoT sensors 105 and cameras 106 by monitoring and capturing the actions of the users and the activities of the machines on the industrial floor utilizing cloud and edge computing services to handle services requested by the users during the manufacturing process flows. For example, contextual situations, such as equipment malfunctions, quality control issues, etc. that occur on the industrial floor of industrial facility 101 are monitored and captured by IoT sensors 105 and cameras 106 by monitoring and capturing the actions of the users involving such contextual situations (e.g., workers are halting production to address breakdown in machinery, workers replacing a broken part in broken machinery) and the activities (e.g., stopping production, rechecking parts to ensure such parts are not defective) of the machines on the industrial floor utilizing cloud and edge computing services to handle services requested by the users (e.g., requesting the service to cease production, requesting the service to recheck products that may be defective) during the manufacturing process flows. In one embodiment, such data may be stored in server 104 and later populated in the knowledge corpus of database 107.

In one embodiment, simulation engine 201 identifies the allowed latency in accessing various services on the industrial floor during the various manufacturing process flows during the contextual situations via simulation. Latency, as used herein, refers to the delay in time in fulfilling the service request, such as completing the service requested by the user (e.g., worker on the industrial floor). For example, such latency may include the time from the user being informed of the contextual situation (e.g., breakdown in machinery) to the time in which the user accesses the service (e.g., requesting the service to cease production, requesting the service to recheck products that may be defective) on the industrial floor via the machine on the industrial floor utilizing cloud and edge computing services to handle such a service request. In another example, such latency may include the time from the user being informed of the contextual situation (e.g., breakdown in machinery) to the time in which the service (e.g., requesting the service to cease production, requesting the service to recheck products that may be defective) requested by the user to address the contextual situation has been completed by the machine on the industrial floor utilizing cloud and edge computing services to handle such a service request. In one embodiment, simulation engine 201 utilizes various simulation tools to perform such a simulation, which can include, but are not limited to, AnyLogic®, FlexSim®, Arena, Siemens® Tecnomatix® Plant Simulation, Virtual Components, etc.

In one embodiment, such simulation tools simulate the time (allowed latency) in user movements throughout industrial facility 101 in addressing the contextual situations by accessing services on the industrial floor during various manufacturing process flows considering factors, such as walking speed, waiting times at the machines on the industrial floor utilizing cloud and edge computing services, and potential interruptions. Such factors may be determined using the historical data pertaining to the types of activities being performed by the users while on the industrial floor for various manufacturing process flows.

In one embodiment, such simulation tools simulate the time (allowed latency) required by the machine on the industrial floor utilizing cloud and edge computing services to complete the service requested by the user to address the contextual situations. Such allowed latency may be determined using the historical data pertaining to the time required by the machines on the industrial floor utilizing cloud and edge computing services to complete the service requested by the user to address the contextual situations.

In one embodiment, such simulation results are stored in database 107 as part of the knowledge corpus. That is, in one embodiment, the contextual situations and the allowed latency in accessing various services on the industrial floor of industrial facility 101 during various manufacturing process floors during the contextual situations are stored in the knowledge corpus of database 107.

In one embodiment, simulation engine 201 receives historical data pertaining to different services to be accessed by the users (e.g., workers) on the industrial floor of industrial facility 101 for various requirements of the service level agreements. A service level agreement, as used herein, refers to a contract between a service provider and a customer that outlines the services to be provided, the standards to be met, and how performance will be measured. In one embodiment, such data may be stored in server 104 and later populated in the knowledge corpus of database 107.

In one embodiment, such data pertaining to the different services to be accessed by the users on the industrial floor of industrial facility 101 is acquired by monitoring and capturing the interactions of the users with the machines via IoT sensors 105, cameras 106 and data capturing tools installed on the machines in connection with the requirements of the service level agreements, which may be stored in server 104 and later populated in the knowledge corpus of database 107. For example, data pertaining to the different services (e.g., requesting the service to increase storage capacity, requesting the service to increase processing speed, etc.) accessed by the users on the industrial floor to satisfy the requirements of particular service level agreements is acquired by IoT sensors 105, cameras 106 and data capturing tools installed on the machines. Data capturing tools, as used herein, refer to tools used to identify which services provided by the machines on the industrial floor utilizing cloud and edge computing services are being accessed by the users on the industrial floor. Examples of such data capturing tools can include, but are not limited to, SailPoint®, JumpCloud®, etc. In one embodiment, such data may be stored in server 104 and later populated in the knowledge corpus of database 107.

In one embodiment, simulation engine 201 identifies the physical locations of the machines on industrial floor 101 utilizing cloud and edge computing services based on the requirements of the service level agreements via simulation. For example, users that request a service to increase the storage capacity may use a particular machine located at a particular location in industrial facility 101 to access such a service.

In one embodiment, simulation engine 201 models worker movements to particular machines (machines utilizing cloud and edge computing services) to access particular services to meet the requirements (e.g., service meets certain replication time, service meets volume conformance goal, service will be available for a minimum of 99.5% of the time, specify how long data can be recovered if it is lost, etc.) of particular service level agreements. For example, simulation engine 201 may model worker movements to a machine (machines utilizing cloud and edge computing services) located at a particular physical location of industrial facility 101 to access a service (e.g., service of increasing the storage capacity) to meet the requirement of the service level agreement (e.g., requirement that the service meets a storage capacity). In one embodiment, simulation engine 201 utilizes various simulation tools to perform such a simulation, which can include, but are not limited to, AnyLogic®, FlexSim®, Arena, Siemens® Tecnomatix® Plant Simulation, Virtual Components, etc.

In one embodiment, such simulation tools simulate user movements throughout industrial facility 101 to utilize particular machines (machines utilizing cloud and edge computing services) located at a particular physical location in industrial facility 101 to access a service (e.g., service of increasing the storage capacity) to meet the requirement of the service level agreement (e.g., requirement that the service meets a storage capacity).

In one embodiment, such simulation results are stored in database 107 as part of the knowledge corpus. That is, in one embodiment, the physical locations of the machines (machines utilizing cloud and edge computing services) on the industrial floor of industrial facility 101 based on the requirements of the service level agreements are stored in the knowledge corpus of database 107.

Infrastructure designer 102 further includes machine learning engine 202 configured to build and train a machine learning model based on the sample data set generated by simulation engine 201 to identify a design of the infrastructure (infrastructure of cloud and edge computing resources) on the industrial floor of industrial facility 101 that optimally services the user, such as the user on the industrial floor, based on the requirements of a service level agreement and a current manufacturing process flow.

In one embodiment, such an identification of the design of the infrastructure (infrastructure of cloud and edge computing resources) includes identifying how much cloud and edge computing resources need to be available at different locations of the industrial floor of industrial facility 101 based on the activities to be performed at different locations of the industrial floor using the trained machine learning model based on a manufacturing process flow.

For example, users (workers) on the industrial floor may require the services of virtual reality interaction at a particular location of the industrial floor to perform the activity of identifying problems in a particular step (e.g., problems with drilling, welding, painting, etc.) in the manufacturing process flow that occurs on the industrial floor. Machines with the required cloud and edge computing resources to provide such services (e.g., virtual reality interaction that provides specific information to the product and process) need to be located close to such users to provide such services.

In one embodiment, the required amount of cloud and edge computing resources that need to be available at a particular location of the industrial floor of industrial facility 101 is determined by the trained machine learning model based on the activities (e.g., virtual reality interaction, controlling forklifts, utilizing caustic cleaning solutions) to be performed and the services (e.g., virtual reality interaction that provides specific information to the product and process) to be accessed by the user on the factory floor at that location according to the current manufacturing process.

Furthermore, in one embodiment, such an identification of the design of the infrastructure (infrastructure of cloud and edge computing resources) includes identifying the machines (machines utilizing cloud and edge computing services) on the industrial floor of industrial facility 101 to be aligned with the activities to be performed at the different locations of the industrial floor using the trained machine learning model based on the requirements of the service level agreement.

For example, in one embodiment, certain machines may be preferable to assist the user in performing activities (e.g., virtual reality interaction, controlling forklifts, utilizing caustic cleaning solutions) and servicing requests (e.g., virtual reality interaction that provides specific information to the product and process) than other machines in industrial facility 101. For instance, the operating characteristics of the machines, including the cloud and edge computing services utilized by such machines as well as its manufacturing capability (e.g., manufacturing work products, such as welding and assembling parts, cutting metal pieces to a precise specification, etc.), if applicable, are stored in a data structure (e.g., table). Such information may be utilized by machine learning engine 202 to train the machine learning model to identify the machines on the industrial floor to be aligned with the activities to be performed, including the services to be accessed, at the different locations on the industrial floor based on the requirements of the service level agreement (e.g., requirement that the service meets a storage capacity). In one embodiment, such a data structure is populated by an expert. In one embodiment, such a data structure is stored in a storage device of infrastructure designer 102.

As a result of the foregoing, the machine learning model is trained to identify a design of the infrastructure (infrastructure of cloud and edge computing resources) on the industrial floor of industrial facility 101 based on the requirements of the service level agreement and the current manufacturing process flow.

In one embodiment, the sample data set discussed above is referred to herein as the “training data,” which is used by a machine learning algorithm to make predictions or decisions, such as the design of the infrastructure (infrastructure of cloud and edge computing resources) on the industrial floor of industrial facility 101 that optimally services the user, such as the user on the industrial floor, based on the requirements of a service level agreement and a current manufacturing process flow. The algorithm iteratively makes predictions on the training data until the predictions achieve the desired accuracy as determined by an expert. Examples of such learning algorithms include nearest neighbor, Naïve Bayes, decision trees, linear regression, support vector machines, and neural networks.

In one embodiment, machine learning engine 202 trains the machine learning model to predict the computational need formed by the requirements of a service level agreement and a manufacturing process flow based on the sample data set generated by simulation engine 201.

In one embodiment, such a sample data set (“training data”) is used by a machine learning algorithm to make predictions or decisions as to the computational need formed by the requirements of a service level agreement and a current manufacturing process flow. The algorithm iteratively makes predictions on the training data until the predictions achieve the desired accuracy as determined by an expert. Examples of such learning algorithms include nearest neighbor, Naïve Bayes, decision trees, linear regression, support vector machines, and neural networks.

Upon training the machine learning model to identify a design of the infrastructure (infrastructure of cloud and edge computing resources) on the industrial floor of industrial facility 101 that optimally services the user, such as the user on the industrial floor, based on the requirements of a service level agreement and a current manufacturing process flow, designer engine 203 of infrastructure designer 102 identifies the design of the infrastructure on the industrial floor of industrial facility 101 using the trained machine learning model based on the received requirements of the service level agreement and the current manufacturing process flow.

In one embodiment, as discussed above, such an identification of the design of the infrastructure (infrastructure of cloud and edge computing resources) includes identifying how much cloud and edge computing resources need to be available at different locations of the industrial floor of industrial facility 101 based on the activities to be performed at different locations of the industrial floor based on a manufacturing process flow. Furthermore, in one embodiment, such an identification of the design of the infrastructure (infrastructure of cloud and edge computing resources) includes identifying the machines (machines utilizing cloud and edge computing services) on the industrial floor of industrial facility 101 to be aligned with the activities to be performed at the different locations of the industrial floor based on the requirements of the service level agreement.

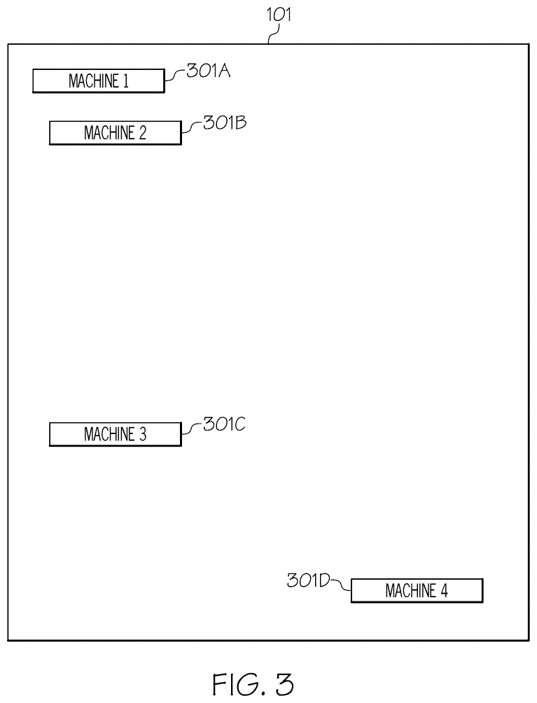

An example of identifying a design of the infrastructure (infrastructure of cloud and edge computing resources) on the industrial floor of industrial facility 101 that optimally services the user, such as the user on the industrial floor, based on the requirements of a service level agreement and a current manufacturing process flow is shown in FIG. 3.

Referring to FIG. 3, FIG. 3 illustrates a design of the infrastructure (infrastructure of cloud and edge computing resources) on the industrial floor of industrial facility 101 that optimally services the user, such as the user on the industrial floor, based on the requirements of a service level agreement and a current manufacturing process flow in accordance with an embodiment of the present disclosure.

As shown in FIG. 3, designer engine 203 identifies the design of the infrastructure (infrastructure of cloud and edge computing resources) on the industrial floor of industrial facility 101 that includes the physical locations of machines 301A-301D (identified as “Machine 1,” “Machine 2,” “Machine 3,” and “Machine 4,” respectively, in FIG. 3) on the industrial floor. Machines 301A-301D may collectively or individually be referred to as machines 301 or machine 301, respectively. Machine 301, as used herein, refers to a computing device, such as an industrial personal computer, panel personal computer, etc., that provides services supported by the cloud and edge computing resources. Furthermore, in one embodiment, such machines 301 may also manufacture work products (e.g., welding and assembling parts, cutting metal pieces to a precise specification, etc.).

In one embodiment, such machines 301 are positioned at designated locations on the industrial floor based, at least in part, on the services required to be provided by the users (e.g., workers) located at various locations within industrial facility 101 that need to be accessed based on the requirements of the service level agreement and the current manufacturing process flow and based on the ability of such machines 301 to fulfill such services using the associated cloud and edge computing resources. In particular, in one embodiment, particular machines 301 (e.g., machines 301A, 301B) may be designed as having edge computing capability located at particular locations within industrial facility 101 that need to be accessed by the users (e.g., workers on the industrial floor), such as in the vicinity of such users, based on the requirements of the service level agreement and the current manufacturing process flow and based on the ability of such machines 301 to fulfill such services using edge computing resources.

Returning to FIG. 2, in conjunction with FIGS. 1 and 3, upon training the machine learning model to predict the computational need formed by the requirements of a service level agreement and a current manufacturing process flow, designer engine 203 is configured to recommend a proposed time slot for machine(s) 301 on the industrial floor of industrial facility 101 to be available for maintenance based on the trained machine learning model's prediction of the computational need formed by the requirements of a service level agreements and a current manufacturing process flow. For example, the trained machine learning model may predict machine 301A needs to be available for providing services to the users located on the industrial floor between 3:00 am until 11:30 pm. As a result, a time slot between 11:30 pm and 3:00 am may be recommended by designer engine 203 for performing maintenance on machine 301A so that the unavailability of machine 301A will not impact the accessibility of services provided by such machine 301A.

In this manner, the design of an infrastructure of cloud and edge computing resources on the industrial floor of an industrial facility that optimally services the user, such as the user on the industrial floor, can be identified.

A further description of these and other features is provided below in connection with the discussion of the method for identifying the design of an infrastructure of cloud and edge computing resources on the industrial floor of an industrial facility that optimally services the user, such as the user on the industrial floor.

Prior to the discussion of the method for identifying the design of an infrastructure of cloud and edge computing resources on the industrial floor of an industrial facility that optimally services the user, such as the user on the industrial floor, a description of the hardware configuration of infrastructure designer 102 (FIG. 1) is provided below in connection with FIG. 4.

Referring now to FIG. 4, in conjunction with FIG. 1, FIG. 4 illustrates an embodiment of the present disclosure of the hardware configuration of infrastructure designer 102 which is representative of a hardware environment for practicing the present disclosure.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 400 contains an example of an environment for the execution of at least some of the computer code (stored in block 401) involved in performing the inventive methods, such as identifying the design of an infrastructure of cloud and edge computing resources on the industrial floor of an industrial facility that optimally services the user, such as the user on the industrial floor. In addition to block 401, computing environment 400 includes, for example, infrastructure designer 102, network 103, such as a wide area network (WAN), end user device (EUD) 402, remote server 403, public cloud 404, and private cloud 405. In this embodiment, infrastructure designer 102 includes processor set 406 (including processing circuitry 407 and cache 408), communication fabric 409, volatile memory 410, persistent storage 411 (including operating system 412 and block 401, as identified above), peripheral device set 413 (including user interface (UI) device set 414, storage 415, and Internet of Things (IoT) sensor set 416), and network module 417. Remote server 403 includes remote database 418. Public cloud 404 includes gateway 419, cloud orchestration module 420, host physical machine set 421, virtual machine set 422, and container set 423.

Infrastructure designer 102 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 418. As is well understood in the art of computer technology, and depending upon the technology, performance of a computer-implemented method may be distributed among multiple computers and/or between multiple locations. On the other hand, in this presentation of computing environment 400, detailed discussion is focused on a single computer, specifically infrastructure designer 102, to keep the presentation as simple as possible. Infrastructure designer 102 may be located in a cloud, even though it is not shown in a cloud in FIG. 4. On the other hand, infrastructure designer 102 is not required to be in a cloud except to any extent as may be affirmatively indicated.

Processor set 406 includes one, or more, computer processors of any type now known or to be developed in the future. Processing circuitry 407 may be distributed over multiple packages, for example, multiple, coordinated integrated circuit chips. Processing circuitry 407 may implement multiple processor threads and/or multiple processor cores. Cache 408 is memory that is located in the processor chip package(s) and is typically used for data or code that should be available for rapid access by the threads or cores running on processor set 406. Cache memories are typically organized into multiple levels depending upon relative proximity to the processing circuitry. Alternatively, some, or all, of the cache for the processor set may be located “off chip.” In some computing environments, processor set 406 may be designed for working with qubits and performing quantum computing.

Computer readable program instructions are typically loaded onto infrastructure designer 102 to cause a series of operational steps to be performed by processor set 406 of infrastructure designer 102 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 408 and the other storage media discussed below. The program instructions, and associated data, are accessed by processor set 406 to control and direct performance of the inventive methods. In computing environment 400, at least some of the instructions for performing the inventive methods may be stored in block 401 in persistent storage 411.

Communication fabric 409 is the signal conduction paths that allow the various components of infrastructure designer 102 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 410 is any type of volatile memory now known or to be developed in the future. Examples include dynamic type random access memory (RAM) or static type RAM. Typically, the volatile memory is characterized by random access, but this is not required unless affirmatively indicated. In infrastructure designer 102, the volatile memory 410 is located in a single package and is internal to infrastructure designer 102, but, alternatively or additionally, the volatile memory may be distributed over multiple packages and/or located externally with respect to infrastructure designer 102.

Persistent Storage 411 is any form of non-volatile storage for computers that is now known or to be developed in the future. The non-volatility of this storage means that the stored data is maintained regardless of whether power is being supplied to infrastructure designer 102 and/or directly to persistent storage 411. Persistent storage 411 may be a read only memory (ROM), but typically at least a portion of the persistent storage allows writing of data, deletion of data and re-writing of data. Some familiar forms of persistent storage include magnetic disks and solid state storage devices. Operating system 412 may take several forms, such as various known proprietary operating systems or open source Portable Operating System Interface type operating systems that employ a kernel. The code included in block 401 typically includes at least some of the computer code involved in performing the inventive methods.

Peripheral device set 413 includes the set of peripheral devices of infrastructure designer 102. Data communication connections between the peripheral devices and the other components of infrastructure designer 102 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 414 may include components such as a display screen, speaker, microphone, wearable devices (such as goggles and smart watches), keyboard, mouse, printer, touchpad, game controllers, and haptic devices. Storage 415 is external storage, such as an external hard drive, or insertable storage, such as an SD card. Storage 415 may be persistent and/or volatile. In some embodiments, storage 415 may take the form of a quantum computing storage device for storing data in the form of qubits. In embodiments where infrastructure designer 102 is required to have a large amount of storage (for example, where infrastructure designer 102 locally stores and manages a large database) then this storage may be provided by peripheral storage devices designed for storing very large amounts of data, such as a storage area network (SAN) that is shared by multiple, geographically distributed computers. IoT sensor set 416 is made up of sensors that can be used in Internet of Things applications. For example, one sensor may be a thermometer and another sensor may be a motion detector.

Network module 417 is the collection of computer software, hardware, and firmware that allows infrastructure designer 102 to communicate with other computers through WAN 103. Network module 417 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 417 are performed on the same physical hardware device. In other embodiments (for example, embodiments that utilize software-defined networking (SDN)), the control functions and the forwarding functions of network module 417 are performed on physically separate devices, such that the control functions manage several different network hardware devices. Computer readable program instructions for performing the inventive methods can typically be downloaded to infrastructure designer 102 from an external computer or external storage device through a network adapter card or network interface included in network module 417.

WAN 103 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 402 is any computer system that is used and controlled by an end user (for example, a customer of an enterprise that operates infrastructure designer 102), and may take any of the forms discussed above in connection with infrastructure designer 102. EUD 402 typically receives helpful and useful data from the operations of infrastructure designer 102. For example, in a hypothetical case where infrastructure designer 102 is designed to provide a recommendation to an end user, this recommendation would typically be communicated from network module 417 of infrastructure designer 102 through WAN 103 to EUD 402. In this way, EUD 402 can display, or otherwise present, the recommendation to an end user. In some embodiments, EUD 402 may be a client device, such as thin client, heavy client, mainframe computer, desktop computer and so on.

Remote server 403 is any computer system that serves at least some data and/or functionality to infrastructure designer 102. Remote server 403 may be controlled and used by the same entity that operates infrastructure designer 102. Remote server 403 represents the machine(s) that collect and store helpful and useful data for use by other computers, such as infrastructure designer 102. For example, in a hypothetical case where infrastructure designer 102 is designed and programmed to provide a recommendation based on historical data, then this historical data may be provided to infrastructure designer 102 from remote database 418 of remote server 403.

Public cloud 404 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 404 is performed by the computer hardware and/or software of cloud orchestration module 420. The computing resources provided by public cloud 404 are typically implemented by virtual computing environments that run on various computers making up the computers of host physical machine set 421, which is the universe of physical computers in and/or available to public cloud 404. The virtual computing environments (VCEs) typically take the form of virtual machines from virtual machine set 422 and/or containers from container set 423. It is understood that these VCEs may be stored as images and may be transferred among and between the various physical machine hosts, either as images or after instantiation of the VCE. Cloud orchestration module 420 manages the transfer and storage of images, deploys new instantiations of VCEs and manages active instantiations of VCE deployments. Gateway 419 is the collection of computer software, hardware, and firmware that allows public cloud 404 to communicate through WAN 103.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 405 is similar to public cloud 404, except that the computing resources are only available for use by a single enterprise. While private cloud 405 is depicted as being in communication with WAN 103 in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 404 and private cloud 405 are both part of a larger hybrid cloud.

Block 401 further includes the software components discussed above in connection with FIGS. 2-3 to identify the design of an infrastructure of cloud and edge computing resources on the industrial floor of an industrial facility that optimally services the user, such as the user on the industrial floor. In one embodiment, such components may be implemented in hardware. The functions discussed above performed by such components are not generic computer functions. As a result, infrastructure designer 102 is a particular machine that is the result of implementing specific, non-generic computer functions.

In one embodiment, the functionality of such software components of infrastructure designer 102, including the functionality for identifying the design of an infrastructure of cloud and edge computing resources on the industrial floor of an industrial facility that optimally services the user, such as the user on the industrial floor, may be embodied in an application specific integrated circuit.

As stated above, infrastructure design for an industrial facility involves planning, developing, and implementing the systems that make the facility function, including: electricity, transportation, water, telecommunications, and data transmission. Some key considerations for industrial facility design include: strategic planning, automation, facility size and expansion, employee safety and comfort, sustainable design, specialized uses and equipment, column bay spacing, etc. Some tools and technologies that can help with the infrastructure design of the industrial facility include building information modeling, which corresponds to a physical and functional model of the facility that helps with visualization, analysis, and improvement. Unfortunately, such tools and technologies do not assist in designing the infrastructure of cloud and edge computing resources utilized at the industrial facility. For example, there are currently no tools or technologies to assist in designing the infrastructure of cloud and edge computing resources utilized at the industrial facility that optimally services the user (i.e., provides the best possible service to the user at the minimum cost), including the user on the industrial floor.

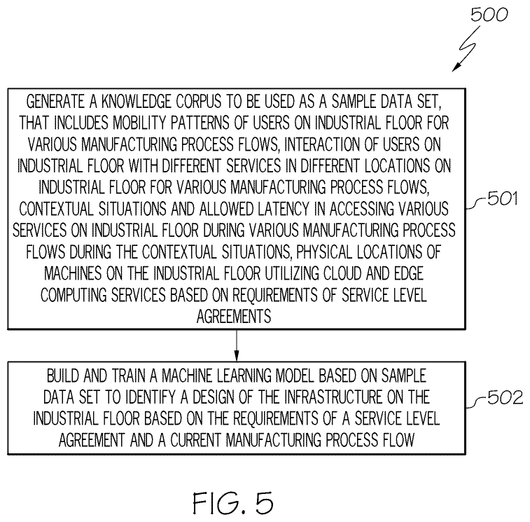

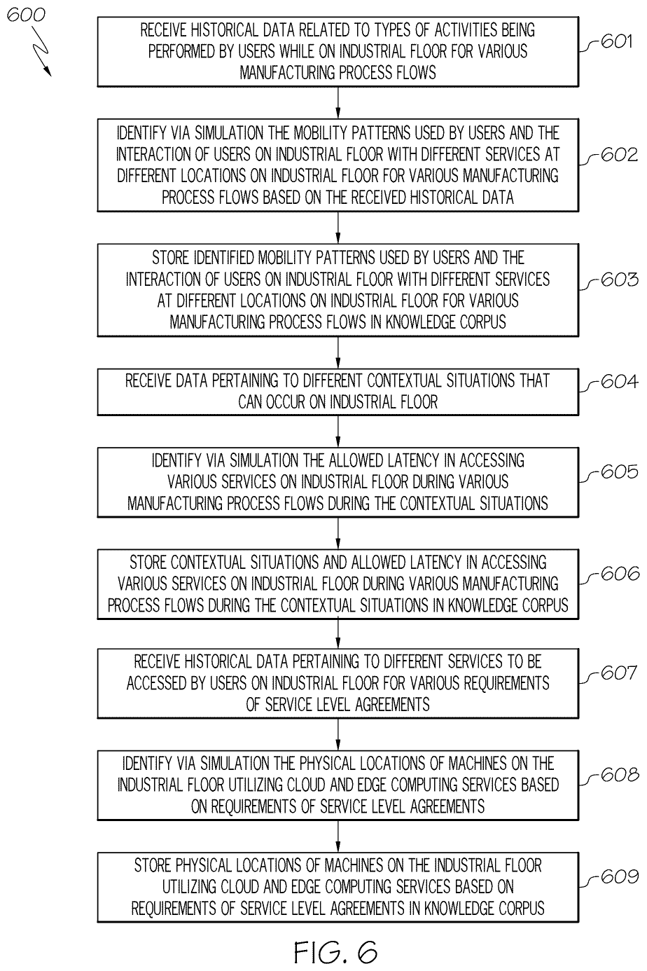

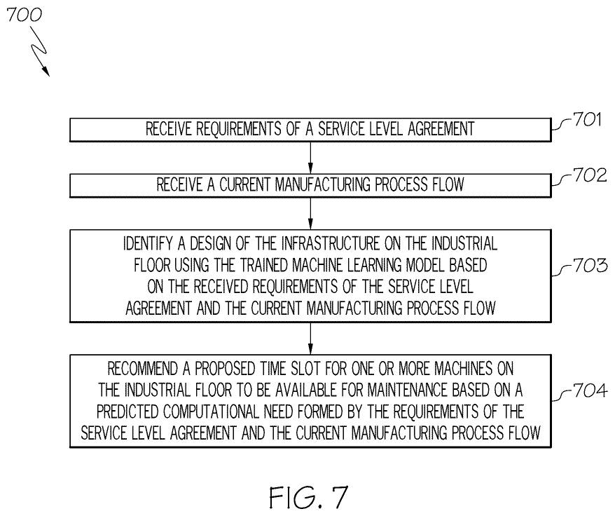

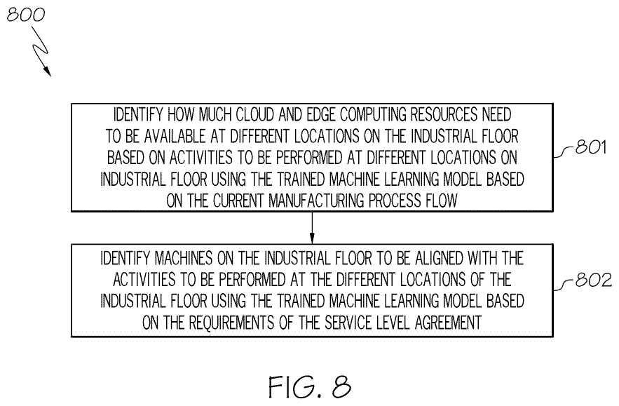

The embodiments of the present disclosure provide a means for identifying a design of an infrastructure of cloud and edge computing resources on the industrial floor of an industrial facility that optimally services the user, such as the user on the industrial floor, as discussed below in connection with FIGS. 5-8. FIG. 5 is a flowchart of a method for training a machine learning model to identify a design of the infrastructure on the industrial floor based on the requirements of a service level agreement and a current manufacturing process flow. FIG. 6 is a flowchart of a method for generating a knowledge corpus to be used as a sample data set for training the machine learning model. FIG. 7 is a flowchart of a method for identifying a design of an infrastructure of cloud and edge computing resources on the industrial floor of an industrial facility that optimally services the user, such as the user on the industrial floor. FIG. 8 is a flowchart of a method for identifying the design of the infrastructure on the industrial floor using the trained machine learning model.

As stated above, FIG. 5 is a flowchart of a method 500 for training a machine learning model to identify a design of the infrastructure on the industrial floor based on the requirements of a service level agreement and a current manufacturing process flow in accordance with an embodiment of the present disclosure.

Referring to FIG. 5, in conjunction with FIGS. 1-4, in operation 501, simulation engine 201 of infrastructure designer 102 generates a knowledge corpus of information stored in database 107 to be used as a sample data set for training a machine learning model to identify a design of the infrastructure on the industrial floor based on the requirements of a service level agreement and a current manufacturing process flow. In one embodiment, such a knowledge corpus of information includes information, such as the mobility patterns (use of mobile devices and applications to enable factory workers to access information, complete tasks, and communicate effectively while moving around the industrial floor) of users on the industrial floor for various manufacturing process flows, interaction of users on the industrial floor with different services at different locations on the industrial floor for various manufacturing process flows, contextual situations and allowed latency in accessing various services on the industrial floor during various manufacturing process flows during the contextual situations, physical locations of machines on the industrial floor utilizing cloud and edge computing services based on the requirements of service level agreements, etc.

A detailed description for generating such a knowledge corpus of information to be used as a sample data set for training a machine learning model to identify a design of the infrastructure on the industrial floor based on the requirements of a service level agreement and a current manufacturing process flow is provided below in connection with FIG. 6.

FIG. 6 is a flowchart of a method 600 for generating a knowledge corpus to be used as a sample data set for training the machine learning model in accordance with an embodiment of the present disclosure.

Referring to FIG. 6, in conjunction with FIGS. 1-5, in operation 601, simulation engine 201 of infrastructure designer 102 receives historical data related to the types of activities being performed by users (e.g., workers) while on the industrial floor of industrial facility 101 for various manufacturing process flows.

As stated above, in one embodiment, such data pertaining to the types of activities being performed by the users while on the industrial floor is acquired by monitoring and capturing the interactions of the users with machines via IoT sensors 105 and cameras 106. For example, activities, such as controlling forklifts remotely, utilizing caustic cleaning solutions, virtual reality interaction, augmented reality interaction, etc., that are utilized by the users via their interactions with the machines on the industrial floor utilizing cloud and edge computing services during the manufacturing process flow are monitored and captured by IoT sensors 105 and cameras 106. In one embodiment, such data may be stored in server 104 and later populated in the knowledge corpus of database 107.

In operation 602, simulation engine 201 of infrastructure designer 102 identifies the mobility patterns used by the users and the interaction of the users on the industrial floor with different services at different locations on the industrial floor for various manufacturing process flows based on such received historical data via simulation. A mobility pattern, as used herein, refers to the use of mobile devices and applications to enable users, such as factory workers, to access information, complete tasks, and communicate effectively while moving around the industrial floor. A service, as used herein, refers to the software functionalities, such as complex computations, data processing, etc. involving the activities (e.g., virtual reality interactions, controlling forklifts, utilizing caustic cleaning solutions, etc.) being performed during the manufacturing process flow.

As discussed above, in one embodiment, simulation engine 201 models worker moments, service points, and different manufacturing process flows enabling the analysis of user interactions on the industrial floor with different services at different locations on the industrial floor for various manufacturing process flows. In one embodiment, simulation engine 201 utilizes various simulation tools to perform such a simulation, which can include, but are not limited to, AnyLogic®, FlexSim®, Arena, Siemens® Tecnomatix® Plant Simulation, Virtual Components, etc.

In one embodiment, such simulation tools simulate user movements throughout industrial facility 101 considering factors, such as walking speed, waiting times at the machines on the industrial floor utilizing cloud and edge computing services, and potential interruptions. Such factors may be determined using the historical data pertaining to the types of activities being performed by the users while on the industrial floor for various manufacturing process flows.

In one embodiment, such simulation tools simulate service interactions, such as which information is accessed, which tasks are completed, etc. using the machines on the industrial floor utilizing cloud and edge computing services. Such service interactions may be determined using the historical data pertaining to the types of activities being performed by the users while on the industrial floor for various manufacturing process flows. For example, such service interactions may include the type of machine, the services processed by such a machine and the required amount of cloud and edge computing resources to provide such services.

In operation 603, simulation engine 201 of infrastructure designer 102 stores such a simulation result, such as the identified mobility patterns used by the users and the interaction of the users on the industrial floor with different services at different locations on the industrial floor for various manufacturing process flows, in the knowledge corpus of database 107.

In operation 604, simulation engine 201 of infrastructure designer 102 receives data pertaining to different contextual situations that can occur on the industrial floor of industrial facility 101 for various manufacturing process flows. In one embodiment, such data may be stored in server 104 and later populated in the knowledge corpus of database 107.

As discussed above, contextual situations, as used herein, refer to events, such as batches, runs, shifts, or any other event that has a start and end time, that involve users and the machines on the industrial floor utilizing cloud and edge computing services to handle services requested by the users during the manufacturing process flows. In one embodiment, such data relates to historical data. In one embodiment, such data is provided by an expert, such as a subject matter expert.

In one embodiment, such data pertaining to different contextual situations that can occur on the industrial floor of industrial facility 101 are monitored and captured by IoT sensors 105 and cameras 106 by monitoring and capturing the actions of the users and the activities of the machines on the industrial floor utilizing cloud and edge computing services to handle services requested by the users during the manufacturing process flows. For example, contextual situations, such as equipment malfunctions, quality control issues, etc. that occur on the industrial floor of industrial facility 101 are monitored and captured by IoT sensors 105 and cameras 106 by monitoring and capturing the actions of the users involving such contextual situations (e.g., workers are halting production to address breakdown in machinery, workers replacing a broken part in broken machinery) and the activities (e.g., stopping production, rechecking parts to ensure such parts are not defective) of the machines on the industrial floor utilizing cloud and edge computing services to handle services requested by the users (e.g., requesting the service to cease production, requesting the service to recheck products that may be defective) during the manufacturing process flows. In one embodiment, such data may be stored in server 104 and later populated in the knowledge corpus of database 107.

In operation 605, simulation engine 201 of infrastructure designer 102 identifies the allowed latency in accessing various services on the industrial floor during the various manufacturing process flows during the contextual situations via simulation.

As stated above, latency, as used herein, refers to the delay in time in fulfilling the service request, such as completing the service requested by the user (e.g., worker on the industrial floor). For example, such latency may include the time from the user being informed of the contextual situation (e.g., breakdown in machinery) to the time in which the user accesses the service (e.g., requesting the service to cease production, requesting the service to recheck products that may be defective) on the industrial floor via the machine on the industrial floor utilizing cloud and edge computing services to handle such a service request. In another example, such latency may include the time from the user being informed of the contextual situation (e.g., breakdown in machinery) to the time in which the service (e.g., requesting the service to cease production, requesting the service to recheck products that may be defective) requested by the user to address the contextual situation has been completed by the machine on the industrial floor utilizing cloud and edge computing services to handle such a service request. In one embodiment, simulation engine 201 utilizes various simulation tools to perform such a simulation, which can include, but are not limited to, AnyLogic®, FlexSim®, Arena, Siemens® Tecnomatix® Plant Simulation, Virtual Components, etc.

In one embodiment, such simulation tools simulate the time (allowed latency) in user movements throughout industrial facility 101 in addressing the contextual situations by accessing services on the industrial floor during various manufacturing process flows considering factors, such as walking speed, waiting times at the machines on the industrial floor utilizing cloud and edge computing services, and potential interruptions. Such factors may be determined using the historical data pertaining to the types of activities being performed by the users while on the industrial floor for various manufacturing process flows.

In one embodiment, such simulation tools simulate the time (allowed latency) required by the machine on the industrial floor utilizing cloud and edge computing services to complete the service requested by the user to address the contextual situations. Such allowed latency may be determined using the historical data pertaining to the time required by the machines on the industrial floor utilizing cloud and edge computing services to complete the service requested by the user to address the contextual situations.

In operation 606, simulation engine 201 of infrastructure designer 102 stores such simulation results, such as the contextual situations and the allowed latency in accessing various services on the industrial floor of industrial facility 101 during various manufacturing process floors during the contextual situations, in the knowledge corpus of database 107.

In operation 607, simulation engine 201 of infrastructure designer 102 receives historical data pertaining to different services to be accessed by the users (e.g., workers) on the industrial floor of industrial facility 101 for various requirements of the service level agreements. In one embodiment, such data may be stored in server 104 and later populated in the knowledge corpus of database 107.

As stated above, a service level agreement, as used herein, refers to a contract between a service provider and a customer that outlines the services to be provided, the standards to be met, and how performance will be measured.

In one embodiment, such data pertaining to the different services to be accessed by the users on the industrial floor of industrial facility 101 is acquired by monitoring and capturing the interactions of the users with the machines via IoT sensors 105, cameras 106 and data capturing tools installed on the machines in connection with the requirements of the service level agreements, which may be stored in server 104 and later populated in the knowledge corpus of database 107. For example, data pertaining to the different services (e.g., requesting the service to increase storage capacity, requesting the service to increase processing speed, etc.) accessed by the users on the industrial floor to satisfy the requirements of particular service level agreements is acquired by IoT sensors 105, cameras 106 and data capturing tools installed on the machines. Data capturing tools, as used herein, refer to tools used to identify which services provided by the machines on the industrial floor utilizing cloud and edge computing services are being accessed by the users on the industrial floor. Examples of such data capturing tools can include, but are not limited to, SailPoint®, JumpCloud®, etc. In one embodiment, such data may be stored in server 104 and later populated in the knowledge corpus of database 107.

In operation 608, simulation engine 201 of infrastructure designer 102 identifies the physical locations of the machines on industrial floor 101 utilizing cloud and edge computing services based on the requirements of the service level agreements via simulation. For example, users that request a service to increase the storage capacity may use a particular machine located at a particular location in industrial facility 101 to access such a service.

As discussed above, in one embodiment, simulation engine 201 models worker movements to particular machines (machines utilizing cloud and edge computing services) to access particular services to meet the requirements (e.g., service meets certain replication time, service meets volume conformance goal, service will be available for a minimum of 99.5% of the time, specify how long data can be recovered if it is lost, etc.) of particular service level agreements. For example, simulation engine 201 may model worker movements to a machine (machines utilizing cloud and edge computing services) located at a particular physical location of industrial facility 101 to access a service (e.g., service of increasing the storage capacity) to meet the requirement of the service level agreement (e.g., requirement that the service meets a storage capacity). In one embodiment, simulation engine 201 utilizes various simulation tools to perform such a simulation, which can include, but are not limited to, AnyLogic®, FlexSim®, Arena, Siemens® Tecnomatix® Plant Simulation, Virtual Components, etc.

In one embodiment, such simulation tools simulate user movements throughout industrial facility 101 to utilize particular machines (machines utilizing cloud and edge computing services) located at a particular physical location in industrial facility 101 to access a service (e.g., service of increasing the storage capacity) to meet the requirement of the service level agreement (e.g., requirement that the service meets a storage capacity).

In operation 609, simulation engine 201 of infrastructure designer 102 stores such simulation results, such as the physical locations of the machines (machines utilizing cloud and edge computing services) on the industrial floor of industrial facility 101 based on the requirements of the service level agreements, in the knowledge corpus of database 107.

Returning to FIG. 5, in conjunction with FIGS. 1-4 and 6, in operation 502, machine learning engine 202 of infrastructure designer 102 builds and trains a machine learning model based on the sample data set generated by simulation engine 201 to identify a design of the infrastructure (infrastructure of cloud and edge computing resources) on the industrial floor of industrial facility 101 that optimally services the user, such as the user on the industrial floor, based on the requirements of a service level agreement and a current manufacturing process flow.

As stated above, in one embodiment, such an identification of the design of the infrastructure (infrastructure of cloud and edge computing resources) includes identifying how much cloud and edge computing resources need to be available at different locations of the industrial floor of industrial facility 101 based on the activities to be performed at different locations of the industrial floor based on a manufacturing process flow. Furthermore, in one embodiment, such an identification of the design of the infrastructure (infrastructure of cloud and edge computing resources) includes identifying the machines (machines utilizing cloud and edge computing services) on the industrial floor of industrial facility 101 to be aligned with the activities to be performed at the different locations on the industrial floor based on the requirements of the service level agreement. For example, in one embodiment, certain machines may be preferable to fulfill certain service requests (e.g., service of increasing the storage capacity) than other machines in industrial facility 101. As a result, the machine learning model is trained to identify the machines on the industrial floor that should be utilized to access the service that is required to be accessed in order to meet the requirements of the service level agreement based on the cloud and edge computing resources of such machines.

In one embodiment, the sample data set discussed above is referred to herein as the “training data,” which is used by a machine learning algorithm to make predictions or decisions, such as the design of the infrastructure (infrastructure of cloud and edge computing resources) on the industrial floor of industrial facility 101 that optimally services the user, such as the user on the industrial floor, based on the requirements of a service level agreement and a current manufacturing process flow. The algorithm iteratively makes predictions on the training data until the predictions achieve the desired accuracy as determined by an expert. Examples of such learning algorithms include nearest neighbor, Naïve Bayes, decision trees, linear regression, support vector machines, and neural networks.

In one embodiment, machine learning engine 202 trains the machine learning model to predict the computational need formed by the requirements of a service level agreement and a manufacturing process flow based on the sample data set generated by simulation engine 201.

In one embodiment, such a sample data set (“training data”) is used by a machine learning algorithm to make predictions or decisions as to the computational need formed by the requirements of a service level agreement and a current manufacturing process flow. The algorithm iteratively makes predictions on the training data until the predictions achieve the desired accuracy as determined by an expert. Examples of such learning algorithms include nearest neighbor, Naïve Bayes, decision trees, linear regression, support vector machines, and neural networks.

Upon training the machine learning model to identify a design of the infrastructure (infrastructure of cloud and edge computing resources) on the industrial floor of industrial facility 101 that optimally services the user, such as the user on the industrial floor, based on the requirements of a service level agreement and a current manufacturing process flow, designer engine 203 of infrastructure designer 102 identifies the design of the infrastructure on the industrial floor of industrial facility 101 using the trained machine learning model based on the received requirements of the service level agreement and the current manufacturing process flow as discussed below in connection with FIG. 7.

FIG. 7 is a flowchart of a method 700 for identifying a design of an infrastructure of cloud and edge computing resources of an industrial facility that optimally services the user, such as the user on the industrial floor, in accordance with an embodiment of the present disclosure.

Referring to FIG. 7, in conjunction with FIGS. 1-6, in operation 701, designer engine 203 of infrastructure designer 102 receives the requirements of a service level agreement.

In one embodiment, such requirements may be inputted to infrastructure designer 102 by a user and received by designer engine 203 via various means, such as the user inputting such information via a keyboard, mouse, touchscreen, etc. For example, a dialog on the user interface of infrastructure designer 102 may appear to the user of infrastructure designer 102 requesting the requirements of the service level agreement.

In operation 702, designer engine 203 of infrastructure designer 102 receives a current manufacturing process flow. A manufacturing process flow, as used herein, refers to a detailed description of each step in the process of manufacturing a product, including a listing of activities to be performed at different locations on the industrial floor involving services provided by the cloud and edge computing resources.

In one embodiment, designer engine 203 receives the current manufacturing process flow from flow manufacturing software of industrial facility 101, which is configured to provide line design, production execution, and demand management. Examples of such flow manufacturing software can include, but are not limited to, Oracle® Flow Manufacturing, ProjectManager, etc.

In operation 703, designer engine 203 of infrastructure designer 102 identifies the design of the infrastructure (infrastructure of cloud and edge computing resources) on the industrial floor of industrial facility 101 that optimally services the user, such as the user on the industrial floor, using the trained machine learning model based on the requirements of the service level agreement and the current manufacturing process flow.

A discussion regarding identifying the design of the infrastructure on the industrial floor using the trained machine learning model is provided below in connection with FIG. 8.

FIG. 8 is a flowchart of a method 800 for identifying the design of the infrastructure on the industrial floor using the trained machine learning model in accordance with an embodiment of the present disclosure.

Referring to FIG. 8, in conjunction with FIGS. 1-7, in operation 801, designer engine 203 of infrastructure designer 102 identifies how much cloud and edge computing resources need to be available at different locations on the industrial floor of industrial facility 101 based on the activities to be performed at different locations on the industrial floor using the trained machine learning model based on the current manufacturing process flow.

For example, users (workers) on the industrial floor may require the services of virtual reality interaction at a particular location of the industrial floor to perform the activity of identifying problems in a particular step (e.g., problems with drilling, welding, painting, etc.) in the manufacturing process flow that occurs on the industrial floor. Machines 301 with the required cloud and edge computing resources to provide such services (e.g., virtual reality interaction that provides specific information to the product and process) need to be located close to such users to provide such services.

In one embodiment, the required amount of cloud and edge computing resources that need to be available at a particular location of the industrial floor of industrial facility 101 is determined by the trained machine learning model based on the activities (e.g., virtual reality interaction, controlling forklifts, utilizing caustic cleaning solutions) to be performed and the services (e.g., virtual reality interaction that provides specific information to the product and process) to be accessed by the user on the factory floor at that location according to the current manufacturing process.

In operation 802, designer engine 203 of infrastructure designer 102 identifies the machines (machines utilizing cloud and edge computing services) on the industrial floor of industrial facility 101 to be aligned with the activities to be performed at the different locations of the industrial floor using the trained machine learning model based on the requirements of the service level agreement.

As discussed above, for example, in one embodiment, certain machines may be preferable to assist the user in performing activities (e.g., virtual reality interaction, controlling forklifts, utilizing caustic cleaning solutions) and servicing requests (e.g., virtual reality interaction that provides specific information to the product and process) than other machines in industrial facility 101. For instance, the operating characteristics of the machines, including the cloud and edge computing services utilized by such machines as well as its manufacturing capability (e.g., manufacturing work products, such as welding and assembling parts, cutting metal pieces to a precise specification, etc.), if applicable, are stored in a data structure (e.g., table). Such information may be utilized by machine learning engine 202 to train the machine learning model to identify the machines on the industrial floor to be aligned with the activities to be performed, including the services to be accessed, at the different locations on the industrial floor based on the requirements of the service level agreement (e.g., requirement that the service meets a storage capacity). In one embodiment, such a data structure is populated by an expert. In one embodiment, such a data structure is stored in a storage device (e.g., storage device 411, 415) of infrastructure designer 102.

Furthermore, as discussed above, an example of identifying a design of the infrastructure (infrastructure of cloud and edge computing resources) on the industrial floor of industrial facility 101 that optimally services the user, such as the user on the industrial floor, based on the requirements of a service level agreement and a current manufacturing process flow is shown in FIG. 3.

As shown in FIG. 3, designer engine 203 identifies the design of the infrastructure (infrastructure of cloud and edge computing resources) on the industrial floor of industrial facility 101 that includes the physical locations of machines 301A-301D on the industrial floor. Machine 301, as used herein, refers to a computing device, such as an industrial personal computer, panel personal computer, etc., that provides services supported by the cloud and edge computing resources. Furthermore, in one embodiment, such machines 301 may also manufacture work products (e.g., welding and assembling parts, cutting metal pieces to a precise specification, etc.).

In one embodiment, such machines 301 are positioned at designated locations on the industrial floor based, at least in part, on the services required to be provided by the users (e.g., workers) located at various locations within industrial facility 101 that need to be accessed based on the requirements of the service level agreement and the current manufacturing process flow and based on the ability of such machines 301 to fulfill such services using the associated cloud and edge computing resources. In particular, in one embodiment, particular machines 301 (e.g., machines 301A, 301B) may be designed as having edge computing capability located at particular locations within industrial facility 101 that need to be accessed by the users (e.g., workers on the industrial floor), such as in the vicinity of such users, based on the requirements of the service level agreement and the current manufacturing process flow and based on the ability of such machines 301 to fulfill such services using edge computing resources.

Returning to FIG. 7, in conjunction with FIGS. 1-6 and 8, upon training the machine learning model to predict the computational need formed by the requirements of a service level agreement and a current manufacturing process flow, in operation 704, designer engine 203 of infrastructure designer 102 recommends a proposed time slot for machine(s) 301 on the industrial floor of industrial facility 101 to be available for maintenance based on the trained machine learning model's prediction of the computational need formed by the requirements of the service level agreement and the current manufacturing process flow.

For example, the trained machine learning model may predict machine 301A needs to be available for providing services to the users located on the industrial floor between 3:00 am until 11:30 pm. As a result, a time slot between 11:30 pm and 3:00 am may be recommended by designer engine 203 for performing maintenance on machine 301A so that the unavailability of machine 301A will not impact the accessibility of services provided by such machine 301A.

In this manner, the design of an infrastructure of cloud and edge computing resources on the industrial floor of an industrial facility that optimally services the user, such as the user on the industrial floor, can be identified.

Furthermore, the principles of the present disclosure improve the technology or technical field involving infrastructure designs for an industrial facility.

As discussed above, infrastructure design for an industrial facility involves planning, developing, and implementing the systems that make the facility function, including: electricity, transportation, water, telecommunications, and data transmission. Some key considerations for industrial facility design include: strategic planning, automation, facility size and expansion, employee safety and comfort, sustainable design, specialized uses and equipment, column bay spacing, etc. Some tools and technologies that can help with the infrastructure design of the industrial facility include building information modeling, which corresponds to a physical and functional model of the facility that helps with visualization, analysis, and improvement. Unfortunately, such tools and technologies do not assist in designing the infrastructure of cloud and edge computing resources utilized at the industrial facility. For example, there are currently no tools or technologies to assist in designing the infrastructure of cloud and edge computing resources utilized at the industrial facility that optimally services the user (i.e., provides the best possible service to the user at the minimum cost), including the user on the industrial floor.

Embodiments of the present disclosure improve such technology by generating a knowledge corpus of information to be used as a sample data set for training a machine learning model to identify a design of the infrastructure on the industrial floor based on the requirements of a service level agreement and a current manufacturing process flow. In one embodiment, such a knowledge corpus of information includes information, such as the mobility patterns (use of mobile devices and applications to enable factory workers to access information, complete tasks, and communicate effectively while moving around the industrial floor) of users on the industrial floor for various manufacturing process flows, interaction of users on the industrial floor with different services at different locations on the industrial floor for various manufacturing process flows, contextual situations and allowed latency in accessing various services on the industrial floor during various manufacturing process flows during the contextual situations, physical locations of machines on the industrial floor utilizing cloud and edge computing services based on requirements of the service level agreements, etc. In one embodiment, a machine learning model is trained to identify the designs of the infrastructure on the industrial floor of the industrial facility based on the knowledge corpus. Upon receiving the requirements of a service level agreement and the current manufacturing process flow, the trained machine learning model is used to identify the design of the infrastructure of cloud and edge computing resources on the industrial floor of the industrial facility that optimally services the user, such as the user on the industrial floor, based on the requirements of the service level agreement and the current manufacturing process. In this manner, the design of an infrastructure of cloud and edge computing resources on the industry floor of the industrial facility that optimally services the user, such as the user on the industrial floor, can be identified. Furthermore, in this manner, there is an improvement in the technical field involving infrastructure designs for an industrial facility.

The technical solution provided by the present disclosure cannot be performed in the human mind or by a human using a pen and paper. That is, the technical solution provided by the present disclosure could not be accomplished in the human mind or by a human using a pen and paper in any reasonable amount of time and with any reasonable expectation of accuracy without the use of a computer.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A computer-implemented method for identifying a design of an infrastructure on an industrial floor to service a user, the method comprising:
generating a knowledge corpus comprising mobility patterns used by users on the industrial floor and interactions of the users on the industrial floor with different services at different locations on the industrial floor for various manufacturing process flows based on simulating activities being performed by the users while on the industrial floor for various manufacturing process flows;
training a machine learning model to identify designs of infrastructure on the industrial floor based on the knowledge corpus;
receiving requirements of a service level agreement;
receiving a current manufacturing process flow; and
identifying the design of the infrastructure on the industrial floor using the trained machine learning model based on the received requirements of the service level agreement and the current manufacturing process flow.

2. The method as recited in claim 1, wherein the current manufacturing process flow comprises a listing of activities to be performed at different locations of the industrial floor, the method further comprises:
identifying how much cloud and edge computing resources need to be available at the different locations of the industrial floor based on the activities to be performed at the different locations of the industrial floor.

3. The method as recited in claim 2 further comprising:
identifying machines on the industrial floor to be aligned with the activities to be performed at the different locations of the industrial floor, wherein each of the machines is associated with a set of cloud and edge computing resources.

4. The method as recited in claim 1 further comprising:
recommending a proposed time slot for one or more machines of the identified infrastructure design on the industrial floor to be available for maintenance based on a predicted computational need formed by the requirements of the service level agreement and the current manufacturing process flow.

5. The method as recited in claim 1, wherein the design of the infrastructure on the industrial floor comprises a physical location of machines on the industrial floor utilizing cloud and edge computing services, wherein the requirements of the service level agreement comprise a latency in accessing services.

6. The method as recited in claim 1 further comprising:
receiving data pertaining to different contextual situations that can occur on the industrial floor;
identifying via simulation an allowed latency in accessing various services on the industrial floor during various manufacturing process flows during the contextual situations; and
storing the contextual situations and the allowed latency in accessing various services on the industrial floor during various manufacturing process flows during the contextual situations in the knowledge corpus.

7. The method as recited in claim 1 further comprising:
receiving historical data pertaining to different services to be accessed by the users on the industrial floor for various requirements of service level agreements;
identifying via simulation physical locations of machines on the industrial floor utilizing cloud and edge computing services based on the requirements of the service level agreements; and
storing the physical locations of the machines on the industrial floor utilizing the cloud and edge computing services based on the requirements of the service level agreements in the knowledge corpus.

8. A computer program product for identifying a design of an infrastructure on an industrial floor to service a user, the computer program product comprising:
a set of one or more computer-readable storage media; and
program instructions, collectively stored in the set of one or more computer-readable storage media, for causing a processor set to perform the following computer operations:
generating a knowledge corpus comprising mobility patterns used by users on the industrial floor and interactions of the users on the industrial floor with different services at different locations on the industrial floor for various manufacturing process flows based on simulating activities being performed by the users while on the industrial floor for various manufacturing process flows;
training a machine learning model to identify designs of infrastructure on the industrial floor based on the knowledge corpus;
receiving requirements of a service level agreement;
receiving a current manufacturing process flow; and
identifying the design of the infrastructure on the industrial floor using the trained machine learning model based on the received requirements of the service level agreement and the current manufacturing process flow.

9. The computer program product as recited in claim 8, wherein the current manufacturing process flow comprises a listing of activities to be performed at different locations of the industrial floor, wherein the program instructions cause the processer set to perform the following computer operation:
identifying how much cloud and edge computing resources need to be available at the different locations of the industrial floor based on the activities to be performed at the different locations of the industrial floor.

10. The computer program product as recited in claim 9, wherein the program instructions cause the processer set to perform the following computer operation:
identifying machines on the industrial floor to be aligned with the activities to be performed at the different locations of the industrial floor, wherein each of the machines is associated with a set of cloud and edge computing resources.

11. The computer program product as recited in claim 8, wherein the program instructions cause the processer set to perform the following computer operation:
recommending a proposed time slot for one or more machines of the identified infrastructure design on the industrial floor to be available for maintenance based on a predicted computational need formed by the requirements of the service level agreement and the current manufacturing process flow.

12. The computer program product as recited in claim 8, wherein the design of the infrastructure on the industrial floor comprises a physical location of machines on the industrial floor utilizing cloud and edge computing services, wherein the requirements of the service level agreement comprise a latency in accessing services.

13. The computer program product as recited in claim 8, wherein the program instructions cause the processer set to perform the following computer operation:
receiving data pertaining to different contextual situations that can occur on the industrial floor;
identifying via simulation an allowed latency in accessing various services on the industrial floor during various manufacturing process flows during the contextual situations; and
storing the contextual situations and the allowed latency in accessing various services on the industrial floor during various manufacturing process flows during the contextual situations in the knowledge corpus.

14. The computer program product as recited in claim 8, wherein the program instructions cause the processer set to perform the following computer operation:
receiving historical data pertaining to different services to be accessed by the users on the industrial floor for various requirements of service level agreements;
identifying via simulation physical locations of machines on the industrial floor utilizing cloud and edge computing services based on the requirements of the service level agreements; and
storing the physical locations of the machines on the industrial floor utilizing the cloud and edge computing services based on the requirements of the service level agreements in the knowledge corpus.

15. A system, comprising:
a memory for storing a computer program for identifying a design of an infrastructure on an industrial floor to service a user; and
a processor connected to the memory, wherein the processor is configured to execute program instructions of the computer program comprising:
generating a knowledge corpus comprising mobility patterns used by users on the industrial floor and interactions of the users on the industrial floor with different services at different locations on the industrial floor for various manufacturing process flows based on simulating activities being performed by the users while on the industrial floor for various manufacturing process flows;
training a machine learning model to identify designs of infrastructure on the industrial floor based on the knowledge corpus;
receiving requirements of a service level agreement;
receiving a current manufacturing process flow; and
identifying the design of the infrastructure on the industrial floor using the trained machine learning model based on the received requirements of the service level agreement and the current manufacturing process flow.

16. The system as recited in claim 15, wherein the current manufacturing process flow comprises a listing of activities to be performed at different locations of the industrial floor, wherein the program instructions of the computer program further comprise:
identifying how much cloud and edge computing resources need to be available at the different locations of the industrial floor based on the activities to be performed at the different locations of the industrial floor.

17. The system as recited in claim 16, wherein the program instructions of the computer program further comprise:
identifying machines on the industrial floor to be aligned with the activities to be performed at the different locations of the industrial floor, wherein each of the machines is associated with a set of cloud and edge computing resources.

18. The system as recited in claim 15, wherein the program instructions of the computer program further comprise:
recommending a proposed time slot for one or more machines of the identified infrastructure design on the industrial floor to be available for maintenance based on a predicted computational need formed by the requirements of the service level agreement and the current manufacturing process flow.

19. The system as recited in claim 15, wherein the design of the infrastructure on the industrial floor comprises a physical location of machines on the industrial floor utilizing cloud and edge computing services, wherein the requirements of the service level agreement comprise a latency in accessing services.

20. The system as recited in claim 15, wherein the program instructions of the computer program further comprise:
receiving data pertaining to different contextual situations that can occur on the industrial floor;
identifying via simulation an allowed latency in accessing various services on the industrial floor during various manufacturing process flows during the contextual situations; and
storing the contextual situations and the allowed latency in accessing various services on the industrial floor during various manufacturing process flows during the contextual situations in the knowledge corpus.
